(19) United States
(12) Patent Application Publication
(10) Pub. No.: US 2011/0037054 A1
(43) Pub. Date: Feb. 17, 2011

(54) AMOLED WITH CASCADED OLED STRUCTURES

(76) Inventors: Chan-Long Shieh, Paradise Valley, AZ (US); Gang Yu, Santa Barbara, CA (US)

Correspondence Address: ROBERT A. PARSONS, 4000 N. CENTRAL AVENUE, SUITE 1220, PHOENIX, AZ, 85012, US

(21) Appl. No.: 12/542,599

(22) Filed: Aug. 17, 2009

(51) Int. Cl. H01L 51/10; H01L 51/40

(52) U.S. Cl. 257/40; 438/23; 257/59; 257/72; 438/34; 257/E51.022

(57) ABSTRACT

An active matrix organic light emitting display includes a plurality of pixels with each pixel including at least one organic light emitting diode circuit. Each diode circuit producing a predetermined amount of light lm in response to power W applied to the circuit and including n organic light emitting diodes cascaded in series so as to increase voltage dropped across the cascaded diodes by the factor of n, where n is an integer greater than one. Each diode of the n organic light emitting diodes produces approximately 1/n of the predetermined amount of light lm so as to reduce current flowing in the diodes by 1/n. The organic light emitting diode circuit of each pixel includes a thin film transistor current driver with the cascaded diodes connected in the source/drain circuit so the current driver provides the current flowing in the diodes.

### FIELD OF THE INVENTION

This invention generally relates to an active matrix organic light emitting display and more specifically to an AMOLED with improved efficiency.

### BACKGROUND OF THE INVENTION

In virtually all active matrix organic light emitting displays (AMOLED), a drive transistor is connected in series with each organic light emitting diode in each pixel and provides drive current to the diode. The drive transistor may be any of a large variety of thin film transistors (TFT), each of which has advantages and disadvantages. For example, poly silicon TFTs have relatively good performance (i.e. high mobility) and reliability, but have poor uniformity and poor yield due to the large grain size (approximately one micron). Also, poly silicon TFTs are relatively expensive to manufacture. Amorphous silicon (a-Si) TFTs have relatively poor mobility and poor reliability at the large drive current required for an organic light emitting diode but they are relatively inexpensive to manufacture.

To activate the organic light emitting diode (and the circuit) a voltage slightly larger than the threshold voltage is applied to the drive transistor, which then supplies sufficient current to activate the organic light emitting diode. For a typical active matrix, the minimum voltage drop, V_{ds}, across the drive transistor is approximately 5 volts and the voltage drop across the organic light emitting diode is approximately the same. Therefore, approximately one half of the power is wasted on the drive transistor.

Most of the prior art efforts to improve the efficiency of AMOLEDs has been concentrated on reducing the voltage on the organic light emitting diode (V_{OLED}). But lowering V_{OLED} further degrades the power utilization efficiency since more than one half the power is wasted on the drive transistor. Another way to improve the total efficiency is to reduce the voltage across the drive transistor. For a TFT active matrix backplane, the drain current in the saturation region is given by:

I_{ds}=μCₒₓ(W/2*L)(V_{gs}−Vₜₕ)² when V_{ds}>(V_{gs}−Vₜₕ)

To act like a current source, V_{ds} has to be kept larger than (V_{gs}−Vₜₕ). The minimum voltage across the drive transistor is constrained by the voltage (V_{gs}−Vₜₕ) at the maximum drive current. There are several ways to reduce the voltage across the drive transistor including better mobility, larger gate capacitance, and larger W/L ratio. The larger W/L ratio is not a good solution because it requires a larger transistor at the price of poor aperture ratio for the organic light emitting diode. Larger gate capacitance reduces the response time of the TFT and mobility is discussed above in conjunction with the different types of TFTs.

It would be highly advantageous, therefore, to remedy the foregoing and other deficiencies inherent in the prior art.

Accordingly, it is an object of the present invention to provide a new and improved active matrix organic light emitting display with improved efficiency.

It is another object of the present invention to provide a new and improved active matrix organic light emitting display with cascaded organic light emitting diodes.

It is another object of the present invention to provide a new and improved active matrix organic light emitting display in which less expensive a-Si or metal oxide TFTs can be utilized.

It is another object of the present invention to provide new and improved methods of manufacturing active matrix organic light emitting displays.

### SUMMARY OF THE INVENTION

Briefly, to achieve the desired objects of the instant invention in accordance with a preferred embodiment thereof, provided is an organic light emitting diode circuit for use in a pixel of an active matrix display. The light emitting diode circuit includes a thin film transistor current driver having a source/drain circuit and a plurality n of organic light emitting diodes cascaded in series and connected in the source/drain circuit so as to increase the voltage drop across the cascaded diodes by a factor of n and reduce the current flowing in the diodes by 1/n.

The desired objects of the instant invention are further achieved in a method of cascading a plurality of organic light emitting diodes in series. The method includes a step of providing a substrate with a plurality of spaced apart electrical contacts formed on a surface thereof. Bank structures are then patterned on the plurality of electrical contacts so as to define an area for each diode of the plurality of organic light emitting diodes between opposed bank structures on an electrical contact of the plurality of electrical contacts. Vertically upstanding mushroom structures are patterned on the plurality of electrical contacts adjacent edges thereof and multiple layers of organic material are deposited on the electrical contact in the area for each diode of the plurality of organic light emitting diodes between the opposed bank structures using the mushroom structures to guide the deposition. The multiple layers of organic material in each area form an organic light emitting diode with the electrical contact in each area defining a lower contact. An upper contact is deposited on the multiple layers of organic material in the area for each diode using the mushroom structures to guide the deposition. The upper contact on the multiple layers of organic material in the area for each diode contacts the electrical contact in an adjacent area to connect the plurality of organic light emitting diodes in series.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings, in which:

FIG. 1 is a schematic representation of a single organic light emitting diode circuit for an active matrix display;

FIG. 2 is a schematic representation of a cascaded organic light emitting diode circuit for an active matrix display in accordance with the present invention;

FIG. 3 is a graphic illustration of the current versus voltage in the drive transistor and the current versus voltage in the organic light emitting diode or diodes (reversed);

FIG. 4 is a semi-schematic illustration of one embodiment of cascaded organic light emitting diodes in accordance with the present invention;

FIG. 5 is a semi-schematic illustration of another embodiment of cascaded organic light emitting diodes in accordance with the present invention;

FIG. 6 is a simplified cross sectional view illustrating the interconnection of cascaded diodes;

FIG. 7 is a simplified cross sectional view illustrating the connection of cascaded diodes to a TFT for an emulated common anode configuration;

FIG. 8 is a schematic representation of an pixel including RGB light emitting diode circuits in an active matrix color display; and

FIG. 9 is a semi-schematic representation of a white pixel in an active matrix color display using color filters.

### DETAILED DESCRIPTION OF THE DRAWINGS

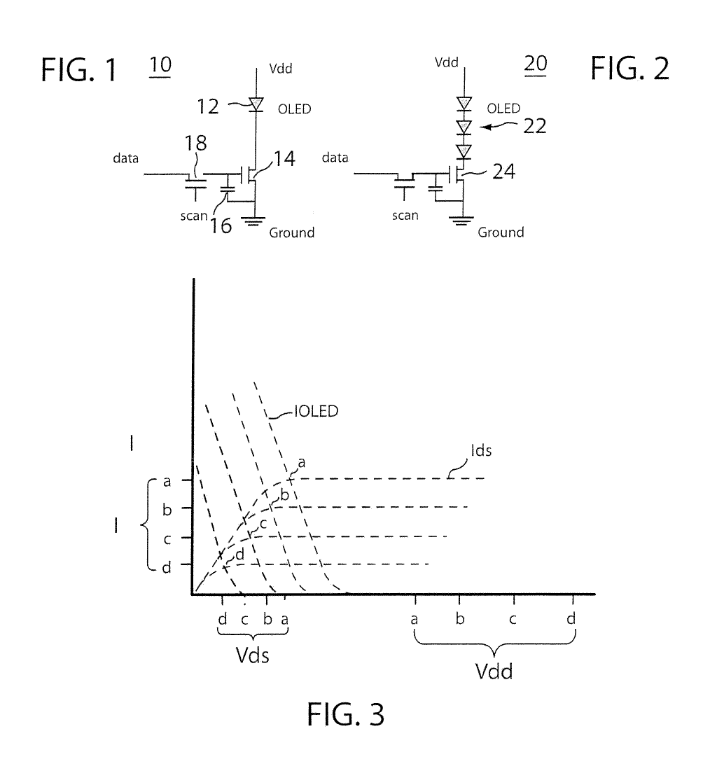

Turning now to FIG. 1, a schematic representation of an organic light emitting diode circuit, designated 10, for an active matrix display is illustrated. It will be understood that several circuits similar to circuit 10 are generally used in each pixel of a full color display but a single circuit 10 is sufficient for an explanation of the present invention. Circuit 10 includes an organic light emitting diode 12 having the anode connected to a source of power (V_{dd}) and the cathode connected to a drive transistor 14. Circuit 10 illustrates a common anode configuration with an n-channel TFT drive transistor. The drain of transistor 14 is connected to the cathode of the organic light emitting diode and the source is connected to ground. A storage capacitor 16 is connected between the gate of transistor 14 and ground and a transistor 18 connects the gate of transistor 14 to a data line in a well known configuration. It is harder to make common anode OLEDs because the anode material of the organic light emitting diode is inherently stable while the cathode is active or unstable. Common cathode configurations may be used but they generally use p-channel transistors which are somewhat more difficult to manufacture and less efficient to use.

To activate organic light emitting diode 12, a voltage is applied to the gate of drive transistor 14 by transistor 18. Drive transistor 14 then supplies sufficient current to activate organic light emitting diode 12. As explained above, in a typical active matrix, the minimum voltage drop, V_{ds}, across drive transistor 14 is approximately 5 volts and the voltage drop across organic light emitting diode 12 is approximately the same. Therefore, one half of the power is “wasted” (i.e. does not produce light) on drive transistor 14.

Turning to FIG. 2, the efficiency problem is primarily solved by cascading a plurality of organic light emitting diodes in series with a drive transistor. In FIG. 2, an improved organic light emitting diode circuit 20 is illustrated. Circuit 20 includes a plurality of organic light emitting diodes 22 connected in series with a drive transistor 24 all connected in an emulated common anode configuration, that is the initial anode at the top of the stack is connected to a common point or source of current. While three cascaded diodes are illustrated, it will be understood from the following disclosure that any convenient number (n) greater than one can be utilized.

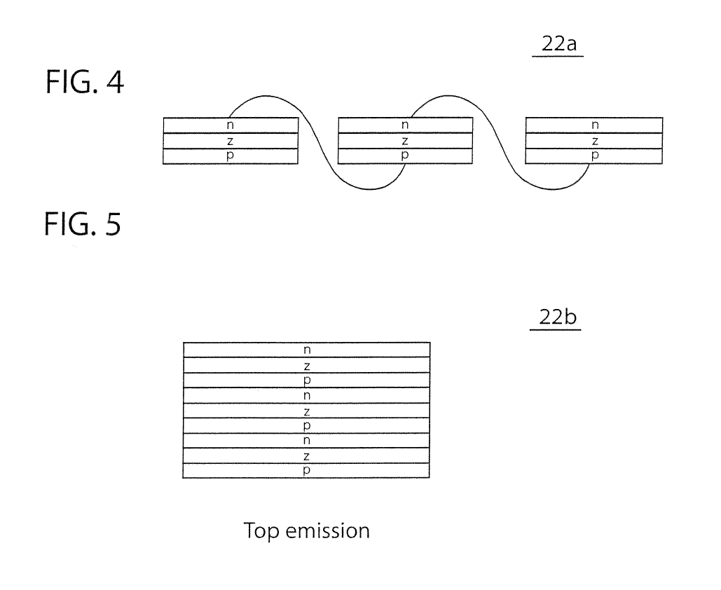

By cascading n organic light emitting diodes 22 in series at each pixel, the voltage of the pixel increases by a factor of n. The n diodes 22 can be cascaded laterally by connecting isolated diodes, as illustrated in FIG. 4. To achieve the same brightness, the current density of the n diodes 22 is the same but each diode has 1/n of the original area and the total current is 1/n of the original single diode (FIG. 1). The n diodes 22 can, alternatively, be stacked vertically as illustrated in FIG. 5. Each stacked diode has the same area as the original single diode (FIG. 1). For the same brightness, the current density can be reduced to 1/n. Thus, the voltage increases by a factor of n and the current and the current density are reduced to 1/n.

Referring additionally to the graphic illustration of FIG. 3, several current versus voltage curves, designated I_{ds}, (for drive transistor 24) are illustrated with several current versus voltage curves, designated I_{OLED}, (for diode 22) illustrated reversed and overlaid on the I_{ds} curves. It will be understood that the current flowing in drive transistor 24 is equal to the current flowing in organic light emitting diodes 22. Also, the supply voltage V_{dd} is the sum of the voltage drop across drive transistor 24 (V_{ds}) and organic light emitting diodes 22 (V_{OLED}). When I_{OLED} and I_{ds} are at point a, V_{ds} is at point a and V_{dd} is at point a (V_{ds}+V_{OLED}). Increasing V_{OLED} by, for example, increasing the number of organic light emitting diodes 22, increases V_{dd} to point b, c, or d. It can be seen that increasing V_{dd} to point b, c, or d causes I_{OLED} to drop to an associated one of points b, c, or d, causing I_{ds} to drop to the associated point b, c, or d. Thus, with cascaded organic light emitting diodes 22, a lower current is needed from drive transistor 24 and the voltage V_{ds} across the source/drain can be reduced slightly because a smaller (V_{gs}−Vₜₕ) is required. Thus, in the present structure, the current is reduced to 1/n and the voltage drop across drive transistor 24 is reduced slightly.

Most importantly, the n diodes raise the total voltage drop across cascaded diodes 22 by a factor of n as illustrated in FIG. 3. That is, each of the n diodes 22 requires the same amount of voltage as the single diode 12 in FIG. 1. The power efficiency per pixel is defined as (V_{OLED}/V_{ds}+V_{OLED}). Where, V_{OLED} is the voltage drop across cascaded diodes 22. A higher pixel voltage can be very beneficial to the power utilization (i.e. efficiency). If V_{ds}=5 volts and the voltage drop across diode 12 is at 4 volts (as in FIG. 1), the power utilization is only 44%. By increasing V_{OLED} through cascading diodes and reducing V_{ds} through better TFT technology and lower diode current, the power utilization efficiency can be greatly improved. Using Novald OLED material data SID 2007, the OLED material power efficacy (no circular polarizer, use color filter instead) is at 13.2 μm/W. Assuming V_{ds} at 5V and no cascading (e.g. FIG. 1), the power efficacy of an AMOLED is about 5 μm/W. Reducing the V_{ds} down to 2.5 V, the power efficacy increases to 7.25 μm/W. With two cascaded diodes and V_{ds} at 2.5V, the power efficacy increases to 9.07 μm/W. With three cascaded diodes and V_{ds} at 2.5V, the power efficacy increases to 10.36 μm/W.

There is another advantage to having a large pixel voltage for the AMOLED in the problem of line resistance, i.e. the resistance of lines connecting pixels in columns and/or rows. For the same format, the drive current increase per line is quadratic with size and the line resistance decrease is only linear with the size. Therefore, the voltage drop on the line increases linearly with the size of the display. On large area displays (thousands to tens of thousands of pixels per line), for example, the drive current can become so large that the voltage across the power line becomes significant compared against the pixel voltage, to contribute to non-uniformity. One way to solve this problem is to use wider metal lines to reduce the line resistance. But this solution comes at the price of sacrificing (i.e. reducing) the aperture ratio. A better solution is to make the pixel into a high voltage, low current device with the same power efficiency as accomplished in the present structure. By making the pixel into a high voltage and low current device, the current on the line is reduced accordingly and the voltage drop across the line is reduced. The reduced voltage drop is small compared against the enhanced voltage drop of the pixel. Therefore, the uniformity is greatly improved.

One way to cascade organic light emitting diodes 22 is to spread individual diodes laterally in the available light emitting area as illustrated in FIG. 4. The diodes are illustrated as three layer structures for convenience, an n-type layer on the top and a p-type layer on bottom, with an illumination layer sandwiched between, although the n-type and p-type layers could be reversed if desired. It will be understood, however, that organic light emitting diodes may include a variety of layers including hole transporting material and electron transporting material. The diodes are isolated from each other and connected in series by connecting a top n-type layer to an adjacent bottom p-type layer. The process of cascading diodes laterally sacrifices the aperture ratio slightly. To achieve the same brightness, the current density of the cascaded diodes is the same but each diode has 1/n of the original area and the total current is 1/n of the current in the original single diode (FIG. 1). Lateral cascading has the advantage of simple fabrication and the freedom to connect either the cathode or the anode to the drive transistor.

Another way to cascade organic light emitting diodes 22 is to stack the diodes vertically as illustrated in FIG. 5. The diodes are illustrated as three layer structures for convenience, a p-type layer on the bottom of each diode and an n-type layer on top. It will be understood, however, that organic light emitting diodes may include a variety of layers and the p-type and n-type layers could be reversed. Vertical stacking requires a tunnel junction between the upper n-type layers and the lower p-type layers of adjacent or overlying diodes (e.g. between electron transporting and the hole transporting materials) so that the manufacturing process is more complicated. Each stacked diode has the same area as the single diode structure (FIG. 1). For the same brightness, the current density can be reduced to 1/n and the reliability of each diode is improved. For compatibility with n-channel TFTs, an emulated common connected anode configuration is preferred so that the anode of the diodes is at the bottom.

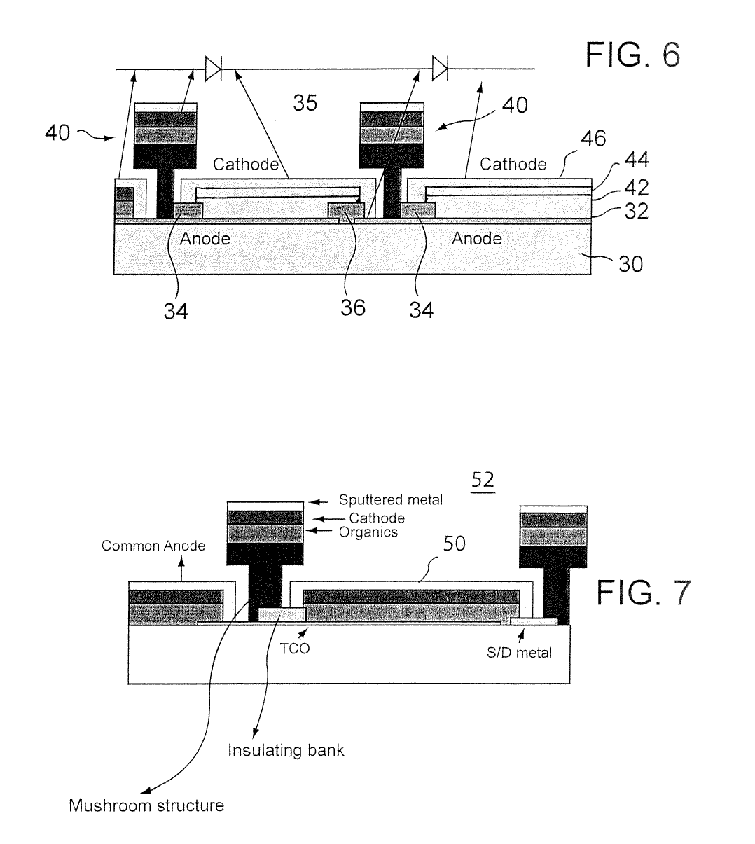

As explained above, there are two ways to cascade organic light emitting diodes, either laterally (FIG. 4) or vertically (FIG. 5). A key challenge in cascading organic light emitting diodes laterally is the difficulty in processing. Referring to FIG. 6, a specific embodiment and method of manufacture is illustrated. In this embodiment, two structures patterned by photolithography are used to define the electrical connections. An insulating bank structure is used to isolate the top electrode from the bottom electrode of a diode and from the bottom electrodes of adjacent diodes. A “mushroom” structure is used to create isolated regions for the top electrodes with high resolution beyond what can be achieved by the shadow mask process.

Referring specifically to FIG. 6, a substrate 30 may be any convenient material but will be transparent in this specific embodiment. For convenience, only two adjacent organic light emitting diodes 35a and 35b are illustrated. An electrically conductive layer 32 is deposited on the upper surface of substrate 30 so as to be divided into bottom contacts 32a, 32b, etc. for separate or discrete diodes. A first insulating bank structure 34a is formed to define one side of organic light emitting diode 35a. A second insulating bank structure 36a defines the opposite side of organic light emitting diode 35a while simultaneously ensuring electrical separation of the bottom contacts 32a and 32b of adjacent diodes 35a and 35b, respectively. Similarly, a first insulating bank structure 34b is formed to define one side of organic light emitting diode 35b and a second insulating bank structure (not shown) defines the opposite side. Bottom contacts 32a and 32b and insulating bank structures 34a, 34b and 36a, etc. are patterned by photolithography using well known techniques. It will be understood that, depending upon the horizontal layout of the embodiment, insulating bank structures 34a and 36a are formed as a common insulating layer surrounding organic light emitting diode 35a and similarly for all the other diode emitting diodes.

Mushroom structures 40 are patterned by photolithography and etching techniques that are well known and do not require further explanation. It will be recognized that mushroom structures 40 are illustrated as T-shaped structures for simplicity and the actual shape may vary substantially from that illustrated, with the further understanding that any structure that performs the functions described below can be utilized and will come within the definition of “mushroom structure”. Depending upon the horizontal layout of the embodiment, mushroom structures 40 are generally formed as a common structure surrounding and defining the limits of each diode 35. With the bank structure or structures and the mushroom structure or structures in place, first layers 42a and 42b of organic material are deposited on the upper surface of each bottom contact 32a and 32b by evaporation. The evaporation of layers 42a and 42b is directional (i.e. generally vertical in FIG. 6) so that deposition of diode 35a, for example, occurs only between bank structures 34a and 36a. The combination of mushroom structures 40 and directional evaporation ensure that deposition is limited to substantially the area between bank structures, e.g. 34a and 36a. As briefly explained above, organic light emitting diodes may include a variety of layers, such as hole transporting, electron blocking, electron transporting, hole blocking, etc., and while the preferred embodiment is to deposit the p-type layer or layers on the bottom, the layers could be reversed (i.e. the n-type layers on the bottom).

It is understood that organic material is very sensitive to damage by radiation and care has to be taken in depositing a top electrode (e.g. a cathode). To protect the organic material, in this preferred embodiment, first layers 44a and 44b of top contact metal are deposited on the upper surface of first layers 42a and 42b, respectively, by directional evaporation. The evaporation is gentle and will not damage the underlying organic material. After the first metal deposition by evaporation, the organic material is protected from subsequent deposition by first metal layers 44a and 44b. In this preferred embodiment, additional interconnecting metal layers 46a and 46b are deposited by other methods such as sputtering, ion beam deposition, CVD, etc., which methods are omni directional and penetrate sideways beneath mushroom structures 40. Interconnecting layer of top electrode 46a is thin enough, relative to the height of mushroom structures 40 that it cannot bridge across mushroom structures 40 and top contact metal layer 44a, for example. However, interconnecting metal layer 46a penetrates sideways beneath mushroom structures 40 to contact the adjacent bottom contact 34b at the edge beyond organic layer 42a and top contact metal layer 44a and bank structure 36a. As can be seen in FIG. 6, the underlying layer at the left of diode 35a is insulating bank 34a so that top electrode 46a is isolated in that region. However, the underlying layer at the right of diode 35a is bottom contact 32b of adjacent diode 35b so that top electrode 46a of diode 35a is connected to the bottom contact of the next adjacent diode 35b in that region.

As illustrated in FIG. 7, the final light emitting diode, designated 35c, in a cascade of light emitting diodes, is illustrated to show the connection of the final diode to the TFT (generally as illustrated schematically in FIG. 1). For convenience in understanding, the various components and layers of light emitting diode 35c are designated with the same numbers as used for light emitting diodes 35a and 35b of FIG. 6. Top electrode 46c of light emitting diode 35c is connected to the source/drain metal, designated 50 (e.g. driver transistor 24 of FIG. 1), which is the underlying layer at the right of diode 35c. As understood in the art, it is generally more difficult to form top anode configurations because of the inherent instability of the cathode metal, which is usually some active material such as lithium and is preferred to be deposited last. However, the lateral cascading process illustrated in FIGS. 6 and 7 can be used to emulate common anode configurations even though the cathode metal is deposited last. For example, the bottom contacts (e.g. anodes) can be connected together by the backplane circuits to emulate a common anode and the isolated top electrodes of each light emitting diode circuit can be connected to the source/drain contact of the TFT to enable driving by an n-channel TFT of a bottom anode OLED.

It should be understood that the OLED illustrated in FIGS. 6 and 7 can be a bottom emission structure or a top emission structure. In a bottom emission structure bottom contacts 32a, 32b, etc. and substrate 30 are transparent. In this example, the top contact metal (layers 44a and 44b, etc.) can be a low resistance metal since it does not have to be transparent. In a top emission structure, layers 44a and 46a, etc. should be at least semi-transparent. Because the top contacts are relatively short and thin low resistance metal is not required and conductivity can be provided by the backplane.

A key challenge in cascading organic light emitting diodes vertically is the tunnel junction between the electron and hole transport materials. With the advance in p-type and n-type doped organic materials, vertical cascading has become possible. The tunnel junction is well known in the art and will not be elaborated upon further.

By cascading a plurality n of organic light emitting diodes in series with a drive transistor, the current flowing in the drive transistor is reduced to 1/n. As explained briefly above, amorphous silicon (a-Si) TFTs have relatively poor mobility and poor reliability at the large drive current required for an organic light emitting diode but they are relatively inexpensive to manufacture. Thus, because of the substantial reduction in drive current through the cascaded diodes, relatively inexpensive amorphous silicon (a-Si) TFTs can be used. Further, metal oxide TFTs, which have a higher mobility than amorphous silicon (a-Si) TFTs and are still relatively inexpensive, can be used as the drive transistors. Metal oxide TFTs and amorphous silicon (a-Si) or nanocrystalline TFTs are generally n-channel transistors that are difficult to incorporate into common anode circuits. However, because of the versatility of the cascading methods and structures disclosed and the substantially reduced current, metal oxide TFTs and amorphous silicon (a-Si) or nanocrystalline TFTs can be relatively easily incorporated into AMOLEDs.

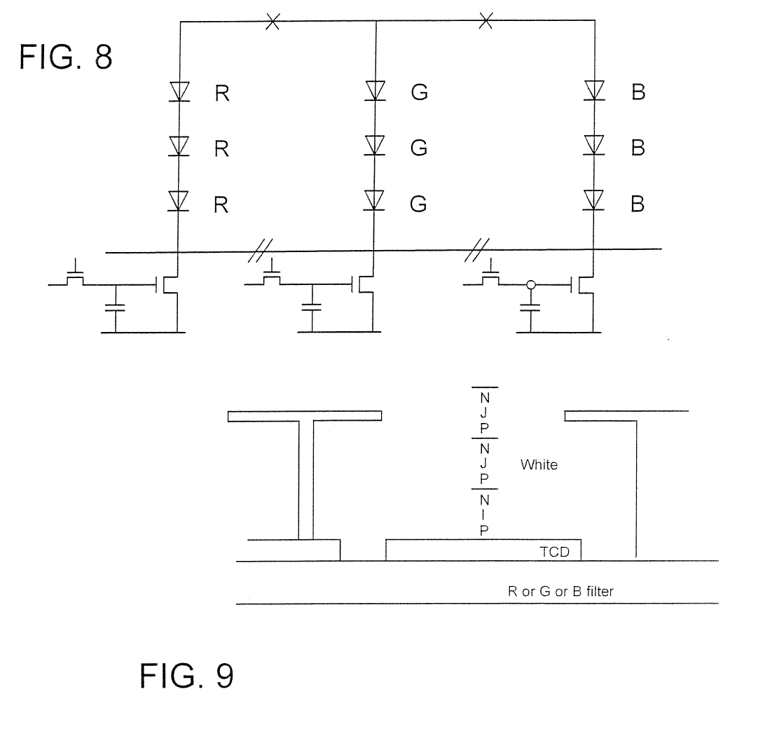

Referring additionally to FIG. 8, a schematic representation is illustrated of a full color pixel, including red, green, and blue light emitting diode circuits, in an active matrix color display. In this example, three cascaded red diodes, three cascaded green diodes and three cascaded blue diodes are illustrated with each diode cascade connected to a TFT control structure. It will be understood from the above disclosure that more or less than three diodes may be cascaded, depending upon the color, application, etc. For example, in many instances blue diodes produce less light and it may be expedient to form the blue diode cascade with more diodes than the green and red cascades.

Referring additionally to FIG. 9, a vertical stack of diodes is illustrated using structure similar to that described in conjunction with FIG. 6 for manufacture. This figure specifically illustrates that more than one diode can be vertically stacked or cascaded in the bank and mushroom embodiment. Further, while the cascades or stacks of diodes illustrated in FIG. 8 can be formed in this manner, FIG. 9 specifically illustrates a stack of white light emitting diodes with a color filter or filters positioned at the bottom. In this example the structure is a bottom emitting OLED and the filter may be formed on the substrate or may simply act as the substrate.

For OLED based color absorption or conversion filters, a major challenge is the lifetime of the organic light emitting diodes. Because of the color attenuation in these types of filters, the organic light emitting diodes have to be driven hard enough to compensate for the loss. By cascading n organic light emitting diodes vertically, the current density is reduced by a factor of n and, therefore, the lifetime is increased by n^{1.5}. Two layers of stacking can improve the lifetime by a factor of 3 and three layers of stacking can improve the lifetime by a factor of 5. Also, vertical cascading can improve the lifetime of a pixel by producing a mixed color light source having all colors produced within one junction, or cascading junctions emitting different colors (e.g. a red diode, a green diode, and a blue diode). Cascading diodes emitting different colors has the additional advantage of being more reliable. For example, since blue diodes are less reliable, it would be advantageous to cascade more blue diodes than other colors in the junction, which would inherently make blue more reliable. Also, vertical and lateral cascading can be combined in some specific applications. For example, lateral cascading can be incorporated to invert the polarity, while vertical cascading can be incorporated to improve the reliability.

Thus, a specific object and advantage of the present invention is to provide a new and improved active matrix organic light emitting display with improved efficiency. The new and improved active matrix organic light emitting display includes cascaded organic light emitting diodes. Another object and advantage of the present invention is that a new and improved active matrix organic light emitting display can be manufactured in which less expensive a-Si or metal oxide TFTs can be utilized. Also, new and improved methods of manufacturing active matrix organic light emitting displays have been disclosed.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. An organic light emitting diode circuit for use in a pixel of an active matrix display comprising:
a thin film transistor current driver having a source/drain circuit; and
a plurality n of organic light emitting diodes cascaded in series and connected in the source/drain circuit so as to increase the voltage drop across the cascaded diodes by a factor of n and reduce the current flowing in the diodes by 1/n.

2. An organic light emitting diode circuit as claimed in claim 1 wherein the n organic light emitting diodes are cascaded laterally.

3. An organic light emitting diode circuit as claimed in claim 1 wherein the n organic light emitting diodes are cascaded vertically.

4. An organic light emitting diode circuit as claimed in claim 1 wherein the thin film transistor current driver includes a metal oxide thin film transistor.

5. An organic light emitting diode circuit as claimed in claim 1 wherein the thin film transistor current driver includes an amorphous or nanocrystalline silicon thin film transistor.

6. An organic light emitting diode circuit as claimed in claim 1 wherein the thin film transistor current driver and the cascaded plurality of organic light emitting diodes are connected in one of an emulated common anode configuration and an emulated common cathode configuration.

7. An active matrix organic light emitting display having a plurality of pixels with each pixel of the plurality of pixels including at least one organic light emitting diode circuit comprising:
an organic light emitting diodes cascaded in series so as to increase voltage dropped across the cascaded diodes by the factor of n and reduce current flowing in the diodes by 1/n, where n is an integer greater than one;
a thin film transistor current driver having a source/drain circuit; and
the cascaded plurality n of organic light emitting diodes connected in the source/drain circuit with the current driver providing the current flowing in the diodes.

8. An active matrix organic light emitting display comprising:
a plurality of pixels with each pixel of the plurality of pixels including at least one organic light emitting diode circuit, the at least one organic light emitting diode circuit of each pixel producing a predetermined amount of light lm in response to power W applied to the circuit;
the at least one organic light emitting diode circuit of each pixel including n organic light emitting diodes cascaded in series so as to increase voltage dropped across the cascaded diodes by the factor of n, where n is an integer greater than one, and each diode of the n organic light emitting diodes producing approximately 1/n of the predetermined amount of light lm so as to reduce current flowing in the diodes by 1/n;
the at least one organic light emitting diode circuit of each pixel including a thin film transistor current driver having a source/drain circuit; and
the cascaded plurality n of organic light emitting diodes connected in the source/drain circuit with the current driver providing the current flowing in the diodes.

9. An organic light emitting diode circuit as claimed in claim 8 wherein the n organic light emitting diodes are cascaded laterally.

10. An organic light emitting diode circuit as claimed in claim 8 wherein the n organic light emitting diodes are cascaded vertically.

11. An organic light emitting diode circuit as claimed in claim 8 wherein the thin film transistor current driver includes a metal oxide thin film transistor.

12. An organic light emitting diode circuit as claimed in claim 8 wherein the thin film transistor current driver includes an amorphous or nanocrystalline silicon thin film transistor.

13. An organic light emitting diode circuit as claimed in claim 8 wherein the thin film transistor current driver and the cascaded plurality of organic light emitting diodes are connected in one of an emulated common anode configuration and an emulated common cathode configuration.

14. A method of cascading a plurality of organic light emitting diodes in series comprising the steps of:
providing a substrate with a plurality of spaced apart electrical contacts formed on a surface thereof;
patterning bank structures on the plurality of electrical contacts so as to define an area for each diode of the plurality of organic light emitting diodes between opposed bank structures on an electrical contact of the plurality of electrical contacts;
patterning vertically upstanding mushroom structures on the plurality of electrical contacts adjacent edges thereof;
depositing multiple layers of organic material on the electrical contact in the area for each diode of the plurality of organic light emitting diodes between the opposed bank structures using the mushroom structures to guide the deposition, the multiple layers of organic material in each area forming an organic light emitting diode with the electrical contact in each area defining a lower contact; and
depositing an upper contact on the multiple layers of organic material in the area for each diode using the mushroom structures to guide the deposition, the upper contact on the multiple layers of organic material in the area for each diode contacting the electrical contact in an adjacent area to connect the plurality of organic light emitting diodes in series.

15. A method as claimed in claim 14 wherein the step of depositing multiple layers of organic material includes directionally depositing by evaporation.

16. A method as claimed in claim 14 wherein the step of depositing an upper contact includes directionally depositing a first portion of the upper contact by evaporation.

17. A method as claimed in claim 16 wherein the step of depositing an upper contact includes omni-directionally depositing a second portion of the upper contact on the first portion by one of sputtering, ion beam deposition, and CVD.

18. A method of cascading a plurality of organic light emitting diodes in series and in a source/drain circuit of a thin film transistor current driver comprising the steps of:
providing a substrate with a plurality of spaced apart electrical contacts formed on a surface thereof and a thin film transistor current driver including a source/drain circuit;
patterning bank structures on the plurality of electrical contacts so as to define an area for each diode of the plurality of organic light emitting diodes between opposed bank structures on an electrical contact of the plurality of electrical contacts;
patterning vertically upstanding mushroom structures on the plurality of electrical contacts adjacent edges thereof;
depositing multiple layers of organic material on the electrical contact in the area for each diode of the plurality of organic light emitting diodes between the opposed bank structures using the mushroom structures to guide the deposition, the multiple layers of organic material in each area forming an organic light emitting diode with the electrical contact in each area defining a lower contact;
depositing an upper contact on the multiple layers of organic material in the area for each diode using the mushroom structures to guide the deposition, the upper contact on the multiple layers of organic material in the area for each diode contacting the electrical contact in an adjacent area to connect the plurality of organic light emitting diodes in series; and
connecting the upper contact of the adjacent area to the source/drain circuit of the thin film transistor current driver.

19. A method as claimed in claim 18 wherein the step of providing a thin film transistor current driver includes providing one of an amorphous or nanocrystalline silicon thin film transistor and a metal oxide thin film transistor.
